(19) United States
(12) Patent Application Publication
(10) Pub. No.: US 2017/0240417 A1
(43) Pub. Date: Aug. 24, 2017

(54) MEMS DEVICE WITH A STABILIZED MINIMUM CAPACITANCE

(71) Applicant: KABUSHIKI KAISHA TOSHIBA, Tokyo (JP)

(72) Inventor: Masaki YAMADA, Saitama (JP)

(21) Appl. No.: 15/210,588

(22) Filed: Jul. 14, 2016

(30) Foreign Application Priority Data
Feb. 18, 2016 (JP) 2016-028777

(51) Int. Cl. B81B 7/00

(52) U.S. Cl. CPC B81B 7/0038; B81B 2203/04; B81B 2201/0221

(57) ABSTRACT

A micro electro mechanical systems (MEMS) device includes a first electrode formed on a substrate, a second electrode that faces the first electrode, a protective film formed on the substrate with a space therebetween in which the first and second electrodes are located, and a sealing layer covering the protective film. The second electrode has a curved structure extending in a direction away from the first electrode, and is movable toward or away from the first electrode. The protective film has a plurality of openings formed therein and a protrusion that protrudes toward the second electrode.

### CROSS-REFERENCE TO RELATED APPLICATION

This application is based upon and claims the benefit of priority from Japanese Patent Application No. 2016-028777, filed Feb. 18, 2016, the entire contents of which are incorporated herein by reference.

### FIELD

Embodiments described herein relate generally to a micro electro mechanical systems (MEMS) device.

### BACKGROUND

A MEMS device, which is configured as an electrical component with a MEMS element, requires a hollow space (cavity) in which a portion of the MEMS element moves. Such a hollow space is formed, for example, with a dome-like thin film structure including a plurality of through holes (a cap layer having openings), a sealing layer that seals the through holes, and a surface protective film that prevents intrusion of moisture, movable ions, and the like.

### DESCRIPTION OF THE DRAWINGS

FIG. 1 is a cross-sectional view of a MEMS device according to an embodiment.

FIGS. 2A and 2B are cross-sectional views of through holes and a protruding portion formed in a cap layer of the MEMS device according to the embodiment.

FIGS. 3A and 3B are cross-sectional views of a structure to illustrate a first manufacturing process of the MEMS device according to the embodiment.

FIGS. 4A and 4B are cross-sectional views of the structure to illustrate a second manufacturing process of the MEMS device according to the embodiment.

FIGS. 5A and 5B are cross-sectional views of the structure to illustrate a third manufacturing process of the MEMS device according to the embodiment.

FIGS. 6A and 6B are cross-sectional views of the structure to illustrate a fourth manufacturing process of the MEMS device according to the embodiment.

### DETAILED DESCRIPTION

An embodiment provides a MEMS device having a stabilized minimum capacity of a variable capacitance element.

In general, according to an embodiment, a micro electro mechanical systems (MEMS) device includes a first electrode formed on a substrate, a second electrode that faces the first electrode, a protective film formed on the substrate with a space therebetween, in which the first and second electrodes are located, and a sealing layer covering the protective film. The second electrode has a curved structure extending in a direction away from the first electrode, and is movable toward or away from the first electrode. The protective film has a plurality of openings formed therein and a protrusion that protrudes toward the second electrode.

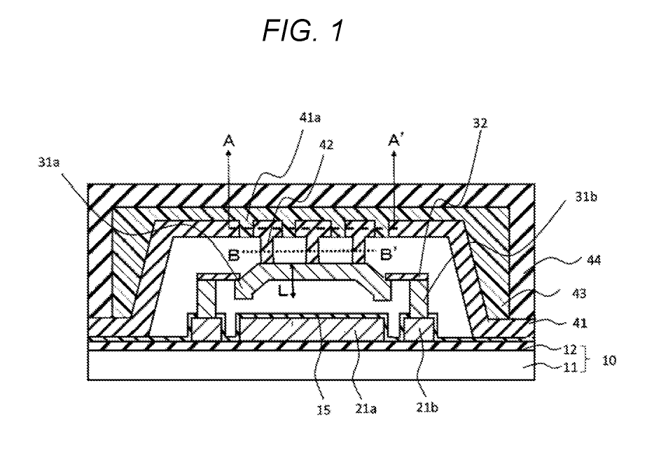

Hereinafter, a MEMS device according to an embodiment will be described with reference to FIG. 1 to FIGS. 6A and 6B. Furthermore, in the below description of the drawings, the same components are described with the same reference numerals. The drawings illustrate schematic views, in which, for example, the illustrated relationship or ratio between thickness and planar dimension may be different from an actual device.

FIG. 1 is a cross-sectional view of the MEMS device according to the embodiment. As illustrated in FIG. 1, a supporting substrate 10 includes a silicon substrate 11 and an insulating film 12, such as a silicon oxide film, which is formed on the silicon substrate 11. The supporting substrate 10 may include an element, such as a field effect transistor of a logic circuit or a memory circuit.

A lower electrode 21a, which serves as a fixed electrode, and a base 21b, on which an anchor portion (beam portion) 31b is fixed, are formed on the supporting substrate 10. The lower electrode 21a is formed, for example, in a rectangular shape and is made from, for example, aluminum (Al) or an alloy thereof. The material used to make the lower electrode 21a is not limited thereto, and can be, for example, copper (Cu), platinum (Pt), tungsten (W), or an alloy containing such metal as a major component. The lower electrode 21a can be divided into a plurality of electrodes. In the present embodiment, the lower electrode 21a and the base 21b can be formed of the same material.

A capacitor insulating film 15 with a thickness of about 100 nm, which is, for example, a silicon nitride film, is formed on the surface of the supporting substrate 10, the lower electrode 21a, and the base 21b. However, the capacitor insulating film 15 is not limited to a silicon nitride film.

An upper electrode 31a, which serves as a movable electrode, is mounted above the lower electrode 21a so as to face the lower electrode 21a. The upper electrode 31a is formed of, for example, a ductile material containing aluminum or an alloy thereof. The material used to form the upper electrode 31a is not limited to such a ductile material, but can be a brittle material, such as tungsten. Furthermore, the anchor portion 31b, which contains the same material as that of the upper electrode 31a, is formed on the base 21b. The base 21b and the anchor portion 31b are fixed to each other. The anchor portion 31b is electrically connected to the supporting substrate 10.

An end portion of the upper electrode 31a is connected to the anchor portion 31b via a spring portion (beam portion) 32. In other words, one end of the spring portion 32 is fixed to the anchor portion 31b, and the other end of the spring portion 32 is fixed to an upper surface of the upper electrode 31a. The spring portion 32 has a wiring layer, via which the spring portion 32 is electrically connected to the anchor portion 31b. Furthermore, although the spring portion 32 and the anchor portion 31b are illustrated as being provided at two positions in FIG. 1, they can be provided at a plurality of positions with respect to the upper electrode 31a. The spring portion 32 includes, for example, a silicon nitride film and has elasticity. The spring portions 32 enable the upper electrode 31a to move up and down with respect to the lower electrode 21a. Here, the upper electrode 31a has a convex structure that the central portion thereof is curved upwardly from the side thereof by virtue of a warping stress of each of the spring portions 32 mounted at both end portions of an upper surface of the upper electrode 31a. The stress acts from the spring portion 32 to the upper electrode 31a. The term “upward” as used herein means “in a direction away from the supporting substrate 10 to a greater distance.” The convex structure of the upper electrode 31a serves to set a distance L between the lowermost surface and the uppermost surface of the upper electrode 31a to, for example, 1 to 2 μm. This distance L is set to a value approximately equal to the film thickness of a second sacrificial layer (described below), or a value equal to or greater than the film thickness of the second sacrificial layer.

The cap layer 41 is formed the upper electrode 31a, the anchor portions 31b and the spring portions 32 so as to cover them with a hollow region (space, cavity) therebetween. The cap layer 41 includes, for example, a silicon oxide film. A protruding portion 42 is provided between the cap layer 41 and the upper electrode 31a, and the protruding portion 42 extends in the direction of the support substrate in a location over the upper electrode 31a and serves as a hard stop that limits the upper electrode 31a movement in the direction away from the support substrate beyond a predetermined range. The protruding portion 42 extends from the cap layer 41, and the protruding portion 42 is a part of the cap layer 41 protruding towards the upper electrode 31a and is thus formed of the same material as that of the cap layer 41. Since the protruding portion 42 and the upper electrode 31a are not affixed to each other, the upper electrode 31a is able to come into contact with and move away from the protruding portion 42 by moving up and down. When a voltage is applied between the upper electrode 31a and the lower electrode 21a, since the upper electrode 31a is attracted to the lower electrode 21a by electrostatic force, the upper electrode 31a moves downward. When the voltage application is stopped, the upper electrode 31a moves upward by the restoring force of the spring portion 32 to return it to the original position thereof. Moreover, the convex structure of the upper electrode 31a enables the upper electrode 31a to be in contact with the protruding portion 42.

The cap layer 41 has, in addition to the protruding portion 42, a plurality of hexagonal through holes 41a, which is used to remove a sacrificial layer to form the open volume in which the upper electrode 31a moves, during the manufacturing process of the MEMS device. The sacrificial layer is a layer provided, for example, between the upper electrode 31a and the lower electrode 21a to shape the hollow region, and is removed later. The through holes 41a are formed in regions of the cap layer 41 overlying the first electrode 31a in which the protruding portion 42 is not formed. Furthermore, although, in FIG. 1, four through holes 41a are illustrated as being formed in the cap layer 41, a greater number of through holes 41a can be formed, and the number of through holes 41a is at least four. If the number of through holes 41a were smaller, a process to remove the sacrificial layer would have to be performed for a long time under a high-temperature condition, so that, in such a case, the upper electrode 31a and the lower electrode 21a would become deformed or damaged.

A sealing resin layer 43 is formed on the upper portion of the cap layer 41 so as to seal the through holes 41a of the cap layer 41. The sealing resin layer 43 is formed not only on the upper surface of the cap layer 41 but also on the side surface of the cap layer 41. An insulating film 44, which serves as a moisture-proof film, is formed on the sealing resin layer 43 so as to cover the cap layer 41 and the sealing resin layer 43. The insulating film 44 includes, for example, a silicon nitride film.

In this way, a movement space for a movable portion of the MEMS element, is formed under a three-layer dome structure including the cap layer 41, the sealing resin layer 43, and the insulating film 44.

Next, a planar structure of the through holes 41a and the protruding portion 42 of the MEMS device is described.

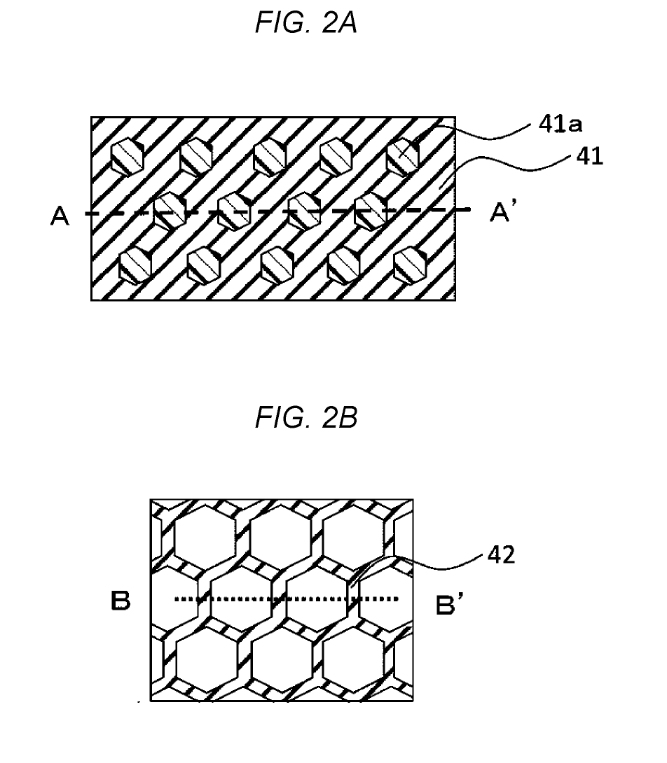

FIG. 2A is a cross-sectional view of the cap layer 41 taken along line A-A′ illustrated in FIG. 1, and FIG. 2B is a cross-sectional view of the cap layer 41 taken along line B-B′ in FIG. 1. As illustrated in FIG. 2A, a plurality of through holes 41a is formed in the cap layer 41. The through holes 41a can be filled with the sealing resin layer 43, which covers the upper surface of the cap layer 41. The through holes 41a are arranged, for example, in a honeycomb structure. The shape of each through hole 41a is a hexagon, but is not limited to a hexagon and is desirably a polygon, the number of sides of which is equal to or greater than that of a hexagon, or a circle. The reason for this is as follows. A material of the sealing resin layer 43, i.e., a sealing resin may flow into the through holes 41a when the sealing resin layer 43 is formed. As the shape of the through holes 41a becomes closer to a circle, the distances from the center point of the through holes 41a to points of the outer circumference thereof become more equal. As a result, it is less likely due to equal surface tension that the sealing resin passes through the through hole 41a and flows into the hollow space. On the other hand, when the shape of the through holes 41a is, for example, a quadrilateral, the distances from the center point of the through holes 41a to points of the outer circumference thereof become unequal. If the distances are unequal, the surface tension becomes low at a portion where the distance from the center point is longer. As a result, the sealing resin may pass through the through holes 41a and flow into the hollow space. If the sealing resin flows into the hollow space, the upper electrode 31a may become adhered to the sealing resin layer 433, and the upward and downward motion of the upper electrode 31a may be restricted. Furthermore, the “outer circumference” used here includes sides and vertices of the polygon. Moreover, the polygon is desirably a regular polygon.

Next, as illustrated in FIG. 2B, the protruding portion 42 in the present embodiment is formed, for example, in a net-like structure, e.g., a honeycomb structure. The “net-like structure” refers to a structure in which the protruding portion 42 is formed like a net from one end to the other end thereof without interruption by the through holes 41a. Furthermore, the structure of the protruding portion 42 is not limited to the net-like structure, but can be another structure as long as the protruding portion 42 is formed at portions other than the through holes 41a. However, the net-like structure, in which the protruding portion 42 is formed in a continuous fashion, increases the strength of the thin-film dome.

Furthermore, the plan views of the through holes 41a and the protruding portion 42 illustrated in FIGS. 2A and 2B are present in only some regions of the MEMS device, and the number or range thereof is not limited to the illustrated one.

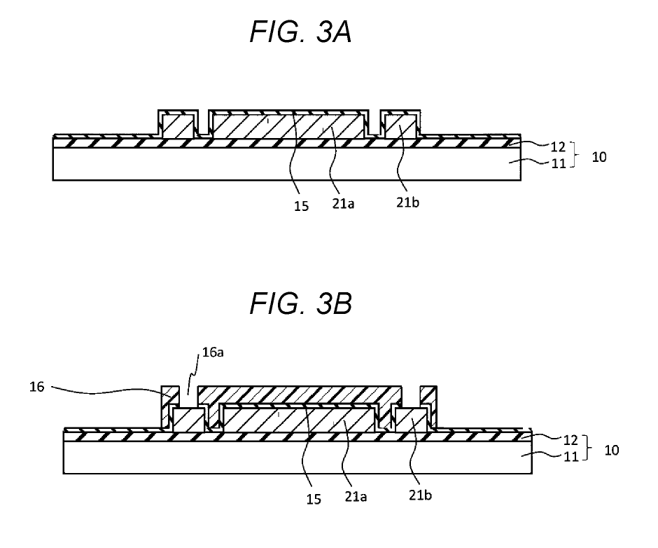

Next, a method of manufacturing the MEMS device according to the present embodiment is described with reference to FIGS. 3A and 3B to FIGS. 6A and 6B.

As illustrated in FIG. 3A, a metal film made from, for example, aluminum with a thickness of several hundred nm to several μm is formed on the supporting substrate 10, which includes the silicon substrate 11 made from, for example, silicon and the insulating film 12, such as a silicon oxide film, which is formed on the silicon substrate 11. Then, the metal film is patterned into the lower electrode 21a and the base 21b. Then, the capacitor insulating film 15, such as a silicon nitride film, is formed by chemical vapor deposition (CVD) or the like on the supporting substrate 10 so as to cover the lower electrode 21a and the base 21b.

Next, as illustrated in FIG. 3B, an organic material, such as polyimide, is applied as a first sacrificial layer 16 and then the first sacrificial layer 16 is patterned into a desired shape. The first sacrificial layer 16 serves as a layer to form a hollow space between the lower electrode 21a and the upper electrode 31a. The first sacrificial layer 16 has opening portions 16a, which are later used to form regions serving as the anchor portions 31b. Then, portions of the capacitor insulating film 15 corresponding to the positions of the opening portions 16a are removed. To form the opening portions 16a, a resist pattern may be formed on the first sacrificial layer 16 by a lithography method and the first sacrificial layer 16 maybe patterned using the resist pattern as a mask by a reactive ion etching (RIE) method.

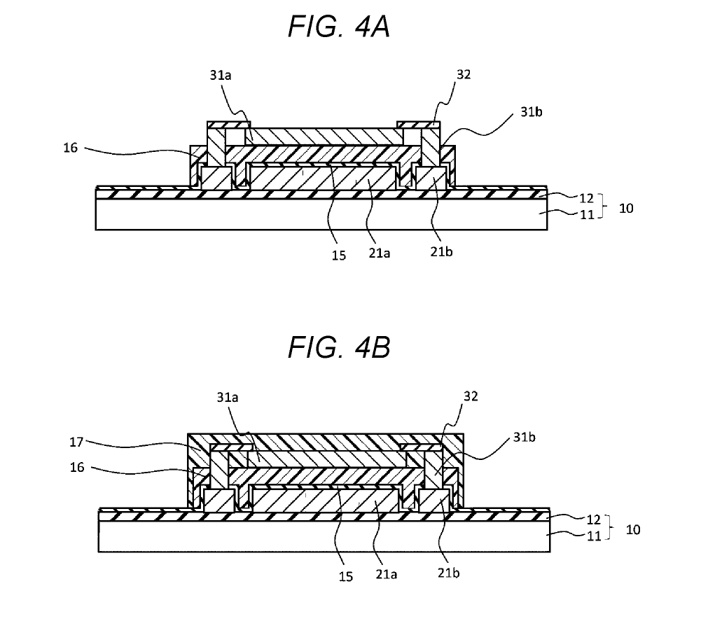

Next, as illustrated in FIG. 4A, the upper electrode 31a and the anchor portions 31b are formed. A metal film made from, for example, aluminum, with a film thickness of several hundred nm to several μm is formed on the first sacrificial layer 16, which has the opening portions 16a. Then, the metal film is patterned into the upper electrode 31a and the anchor portions 31b. After the patterning, the spring portions (beam portions) 32, which interconnect the upper electrode 31a and the anchor portions 31b are formed. The spring portions 32 can be formed by forming, for example, a silicon nitride film and then patterning the silicon nitride film into the desired shapes of the spring portions 32 by the RIE.

Next, as illustrated in FIG. 4B, a second sacrificial layer 17 is formed to form the hollow space above the upper electrode 31a. The second sacrificial layer 17 is formed so as to cover the upper electrode 31a, the anchor portions 31b, and the spring portions 32.

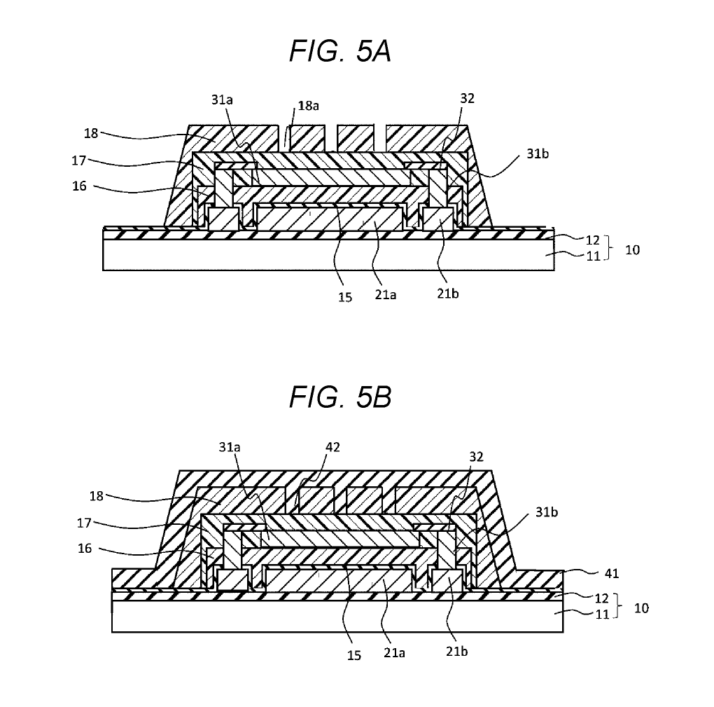

Next, as illustrated in FIG. 5A, a third sacrificial layer 18 is formed on the second sacrificial layer 17. The third sacrificial layer 18 is used to form the hollow space and the protruding portion 42. Then, the third sacrificial layer 18 is patterned into a shape corresponding to the shape of the protruding portion 42 illustrated in FIG. 2B. Thus, this patterning is performed to form the opening portions 18a of the third sacrificial layer 18. Furthermore, the second sacrificial layer 17 and the third sacrificial layer 18 each include a polyimide-based organic material that is the same as or similar to the composition of the first sacrificial layer 16.

Next, a thin-film dome is formed. Specifically, as illustrated in FIG. 5B, an insulating film, such as a silicon oxide film, with a thickness of several hundred nm to several μm is formed by CVD method or the like, a resist (not illustrated) is formed by a lithography method, and then the insulating film is patterned into the cap layer 41 using the resist as a mask. In this instance, an insulating film of the same material as that of the cap layer 41 is filled in the opening portions 18a formed in the sacrificial layer 18, thereby forming the protruding portion 42. At this time, since the second sacrificial layer 17 is formed between the protruding portion 42 and the upper electrode 31a, the protruding portion 42 and the upper electrode 31a are not in contact with each other.

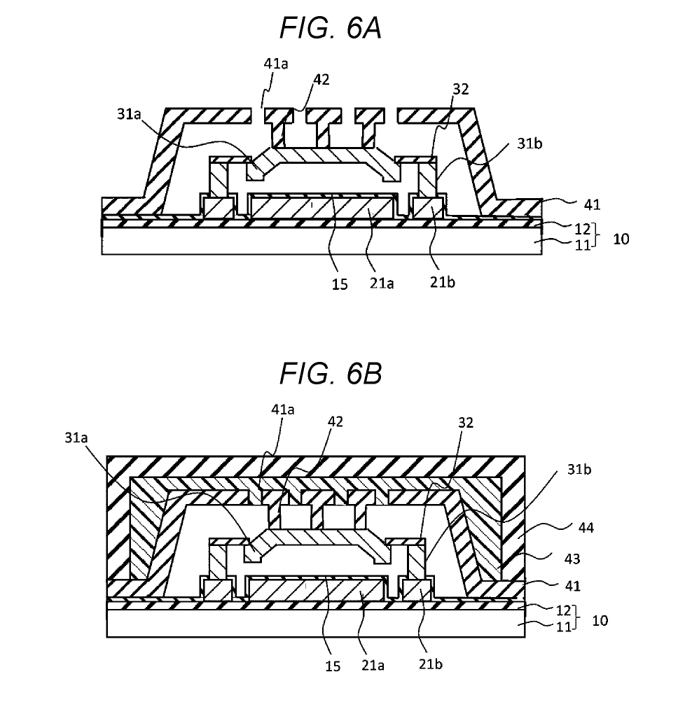

Next, as illustrated in FIG. 6A, in the cap layer 41, the through holes 41a which are to remove the first, second, and third sacrificial layers 16, 17, and 18 are formed by the RIE method or a wet etching method at positions of the cap layer 41 other than the positions where the protruding portion 42 is formed. Then, the first, second, and third sacrificial layers 16, 17, and 18 are removed through the through holes 41a by an ashing method using oxygen gas. As a result, the hollow space is formed around the upper electrode 31a, the anchor portions 31b, and the spring portions 32. Thus, the upper electrode 31a becomes movable up and down via the spring portions 32. When the hollow space is formed by removing the first, second, and third sacrificial layers 16, 17, and 18, an internal stress is exerted from the spring portions 32 to the upper electrode 31a. As a result, the upper electrode 31a forms a convex structure that is curved upwardly, and at this time the upper electrode 31a comes into contact with the protruding portion 42.

Next, as illustrated in FIG. 6B, a polyimide-based organic material is applied on the upper surface and the side surface of the cap layer 41, and then the layer of the polyimide-based organic material is patterned into the sealing resin layer 43. In this instance, the sealing resin layer 43 seals the through holes 41a. However, as described above, surface tension prevents the organic material from flowing into the hollow space from the through holes 41a. Finally, by CVD or the like, the insulating film 44, which serves as a moisture-proofing film, is formed over the entire surface of the supporting substrate 10 so as to cover the cap layer 41 and the sealing resin layer 43. In the above-described way, the MEMS device according to the embodiment is manufactured.

According to the MEMS device of the present embodiment, the protruding portion 42 formed in the cap layer 41 prevents the upper electrode 31a from moving upward beyond a predetermined position, which will stabilize the minimum capacitance of a capacitor formed between the lower electrode 21a and the upper electrode 31a. Also, since the upper electrode 31a is not integrally formed with the protruding portion 42 and the upper electrode 31a is movable, the capacitance of the capacitor can be varied.

Furthermore, the upper electrode 31a has a convex structure that is upwardly curved, i.e., has a convex side facing the support substrate. Since the upper electrode 31a has the downwardly facing convex structure that is curved upwardly in the middle thereof, the upper electrode 31a is less likely to become a concave structure that is curved downwardly in the middle on some events. As a result, the capacitance of the capacitor is less likely to become unexpectedly large.

Moreover, the net-like structure of the protruding portion 42 increases the strength of the thin-film dome.

Even if the through holes 41a are filled with the sealing resin, the protruding portion 42 prevents the upper electrode 31a, when moving upward, from adhering to the sealing resin and becoming immovable. Further, the through holes 41a of the hexagonal shape and the circular shape prevent the sealing resin from flowing into the hollow space.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

What is claimed is:

1. A micro electro mechanical systems (MEMS) device, comprising:
a first electrode formed on a substrate;
a second electrode having a side facing the first electrode, further comprising a curved portion extending in a direction away from the first electrode, and is movable toward and away from the first electrode;
a protective film formed on the substrate with a space in which the first and second electrodes are located therebetween, the protective film having a plurality of openings formed therein and a protrusion extending toward the second electrode; and
a sealing layer covering the protective film.

2. The MEMS device according to claim 1, wherein the plurality of openings have a polygonal shape having a number of sides equal to or greater than six.

3. The MEMS device according to claim 1, wherein the plurality of openings have a circular shape.

4. The MEMS device according to claim 1, wherein the protrusion has a net-like structure.

5. The MEMS device according to claim 1, wherein the protrusion has a honeycomb structure.

6. The MEMS device according to claim 1, further comprising:
an elastic member disposed above the substrate within the space and attached to at least an end portion of an upper surface of the second electrode, wherein
the second electrode is movable by deformation of the elastic member.

7. The MEMS device according to claim 6, wherein
the elastic member is attached to a plurality of the ends of the second electrode.

8. The MEMS device according to claim 6, wherein
the elastic member is attached to an upper surface of the second electrode.

9. The MEMS device according to claim 1, wherein
a distance between a portion of the second electrode that is farthest from the first electrode and a portion of the second electrode that is closest to the first electrode is equal to or greater than 1 μm and equal to or smaller than 2 μm.

10. The MEMS device according to claim 1, wherein
the second electrode is separable from, and contactable with, the protrusion as the second electrode moves.

11. A micro electro mechanical systems (MEMS) device, comprising:
a first electrode formed on a substrate;
a second electrode facing the first electrode and movable toward and away from the first electrode;
a protective film formed on the substrate with a space in which the first and second electrodes are located therebetween, the protective film having a plurality of openings formed therein, each of the openings having at least one of a polygonal shape having sides equal to or greater than six or a circular shape, and a protrusion that protrudes toward the second electrode; and
a sealing layer covering the protective film.

12. The MEMS device according to claim 11, wherein the protrusion has a net-like structure.

13. The MEMS device according to claim 11, the protrusion has a honeycomb structure.

14. The MEMS device according to claim 11, further comprising:
an elastic member disposed above the substrate within the space and attached to at least an end portion of an upper surface of the second electrode, wherein
the second electrode is movable by deformation of the elastic member.

15. The MEMS device according to claim 14, wherein
the elastic member is attached to a plurality of the ends of the second electrode.

16. The MEMS device according to claim 14, wherein
the elastic member is attached to an upper surface of the second electrode.

17. The MEMS device according to claim 11, wherein
the second electrode is separable from, and contactable with, the protrusion as the second electrode moves.

18. A micro electro mechanical systems (MEMS) device, comprising:
a first electrode formed on a substrate;
a second electrode facing the first electrode and movable toward and away from the first electrode;
a protective film formed on the substrate, with a space therebetween in which the first and second electrodes are located, the protective film having a plurality of openings formed therein and a protrusion extending toward the second electrode and has a net-like structure; and
a sealing layer covering the protective film.

19. The MEMS device according to claim 18, wherein the protrusion has a honeycomb structure.

20. The MEMS device according to claim 18, wherein
the second electrode is separable from, and contactable with, the protrusion as the second electrode moves.
